(19) United States
(12) Patent Application Publication
(10) Pub. No.: US 2024/0118313 A1
(43) Pub. Date: Apr. 11, 2024

(54) PROBE HEAD HAVING SPRING PROBES

(71) Applicant: MPI CORPORATION, CHU-PEI CITY (TW)

(72) Inventors: WEI-CHENG KU, CHU-PEI CITY (TW); WEN-YI WANG, CHU-PEI CITY (TW); CHIH-WEI WEN, CHU-PEI CITY (TW)

(73) Assignee: MPI CORPORATION, CHU-PEI CITY (TW)

(21) Appl. No.: 18/377,158

(22) Filed: Oct. 5, 2023

Related U.S. Application Data
(60) Provisional application No. 63/413,626, filed on Oct. 6, 2022.
(60) Provisional application No. 63/446,359, filed on Feb. 17, 2023.

(30) Foreign Application Priority Data
Jun. 2, 2023 (TW) 112120751

(51) Int. Cl. G01R 1/067; G01R 1/073

(52) U.S. Cl. CPC G01R 1/06722; G01R 1/07307

(57) ABSTRACT

A probe head includes upper, middle and lower dies having upper, middle and lower guiding holes respectively, and a plurality of spring probes. The spring probe includes upper and lower abutting sections disposed in the upper and lower guiding holes, a spring section connecting the upper and lower abutting sections, and a barrel disposed on the periphery of the spring section and inserted in the middle guiding hole. The spring probes include adjacent first and second probes whose barrels has first and second outer diameters and are accommodated in first and second middle guiding holes having first and second widths. The difference between the first width and outer diameter and/or the difference between the second width and outer diameter is larger than or equal to 10 micrometers, and/or the difference between the first and second outer diameters is larger than or equal to 5 μm. Alternatively, the middle guiding holes include a multi-probe matching hole, and the outer diameters of two adjacent barrels accommodated therein are larger than the smallest distance therebetween. The present invention is capable of satisfying the test requirements of fine pitch and impedance matching.

### BACKGROUND OF THE INVENTION

### 1. Field of the Invention

The present invention relates to probe heads of probe cards for chip probing (also called CP for short) or probe heads combined with a socket for after-encapsulation IC final tests (also called FT for short) and more particularly, to a probe head having spring probes.

### 2. Description of the Related Art

Referring to FIG. 1, a conventional probe head 10 of a probe card includes a probe seat 11, and a plurality of spring probes 12 inserted in the probe seat 11. An upper die 13 and a lower die 14 are connected with each other to form the probe seat 11. The upper die 13 has a plurality of upper guiding holes 15. The lower die 14 has a plurality of lower guiding holes 16 coaxially corresponding to the upper guiding holes 15 respectively. An accommodating space 17 is provided between the upper and lower dies 13, 14. The spring probe 12 includes a barrel 121, a spring 122 disposed in the barrel 121, an upper abutting section 123 abutted against the top end of the spring 122 and extending upwardly from the inside of the barrel 121 to the outside of the barrel 121, and a lower abutting section 124 abutted against the bottom end of the spring 122 and extending downwardly from the inside of the barrel 121 to the outside of the barrel 121. The upper and lower abutting sections 123, 124 are inserted in the upper and lower guiding holes 15, 16 respectively. The barrel 121 is located in the accommodating space 17.

The probe head 10 is adapted to be combined with a space transformer (not shown) disposed on the top side thereof and a main circuit board (not shown) disposed on the top side of the space transformer, so that they collectively compose a probe card. The top end of the upper abutting section 123 of the spring probe 12 is adapted to be abutted against an electrically conductive contact on the bottom surface of the space transformer, so as to be electrically connected with a tester (not shown) through the space transformer and the main circuit board. Alternatively, there may be no space transformer between the probe head 10 and the main circuit board, such that the top end of the upper abutting section 123 of the spring probe 12 is abutted against an electrically conductive contact on the bottom surface of the main circuit board. The bottom end of the lower abutting section 124 of the spring probe 12 is adapted to contact an electrically conductive contact of a device under test (not shown), so that the tester is electrically connected with the device under test through the probe card.

Compared with other kinds of probes such as cobra or wire needle, the spring probe is more suitable for high-frequency tests (e.g. 50 GHz). The coaxial spring probe, whose central signal conductor and outer cladding ground conductor are separated by dielectric material, is easy for the designing of impedance matching structure thereof, thereby more often used in high-frequency test. However, the coaxial spring probe has a certain diameter and unable to be thinned, so it cannot satisfy the test requirement of fine pitch (for example, pitch P is smaller than 500 vim). Although the normal spring probe 12 (i.e. non-coaxial spring probe) as shown in FIG. 1 can be thinned in diameter to satisfy the test requirement of fine pitch, it is relatively poorer in impedance matching property. Detailedly speaking, most of the outer surface of the spring probe 12 belongs to the barrel 121. The upper and lower abutting sections 123, 124 are relatively shorter, and will receive force to be partially retracted into the barrel 121 during the test. Therefore, the barrel 121 has relatively larger influence on the impedance matching property of the spring probe 12. However, in the probe head 10, only the air located in the accommodating space 17 exists between the barrels 121 of the adjacent spring probes 12, which causes strong impedance and inductance between the adjacent spring probes 12, such that the probe head 10 is unable to satisfy the required impedance matching condition of the probe card.

### SUMMARY OF THE INVENTION

In view of the above-noted defects, it is a primary objective of the present invention to provide a probe head having spring probes, which can satisfy the test requirements of fine pitch and impedance matching.

To attain the above objective, the present invention provides a probe head having spring probes, which includes an upper die, a lower die, a middle die disposed between the upper die and the lower die, and a plurality of spring probes. The upper die includes a plurality of upper guiding holes. The lower die includes a plurality of lower guiding holes. The middle die includes a plurality of middle guiding holes. The spring probes each include an upper abutting section, a lower abutting section, a spring section connecting the upper abutting section and the lower abutting section, and a barrel disposed on the periphery of the spring section. The upper abutting sections of the spring probes are inserted in the upper guiding holes respectively. The lower abutting sections of the spring probes are inserted in the lower guiding holes respectively. The barrels of the spring probes are inserted in the middle guiding holes respectively. The plurality of spring probes include a first probe and a second probe, which are located adjacent to each other. The barrel of the first probe and the barrel of the second probe have a first outer diameter and a second outer diameter respectively. The plurality of middle guiding holes include a first middle guiding hole and a second middle guiding hole, which accommodate the first probe and the second probe respectively. The first middle guiding hole and the second middle guiding hole have a first width and a second width respectively. The difference between the first width and the first outer diameter is defined as a first difference. The difference between the second width and the second outer diameter is defined as a second difference. The difference between the first outer diameter and the second outer diameter is defined as a third difference. The probe head satisfies at least one of the following three conditions: the first difference being larger than or equal to 10 micrometers, the second difference being larger than or equal to 10 micrometers, and the third difference being larger than or equal to 5 micrometers.

As a result, the spring probes in the present invention are normal non-coaxial spring probes, and able to be manufactured with the required outer diameter according to the test requirement, thereby capable of satisfying the test requirement of fine pitch. Besides, the spring probes are disposed in the middle guiding holes of the middle die in a one-to-one manner, so that not only the air located in the middle guiding hole but also the partial solid middle die (i.e. the wall thickness of the middle die located between the adjacent middle guiding holes) exist between the barrels of the adjacent spring probes. Compared with such case without middle die as described in the description of the related art, the middle die in the present invention will cause raised capacitance value and lowered impedance between the adjacent barrels. However, in order to prevent the capacitance value from being so high as to result in that the impedance is slightly lower than the expected value, the widths of the middle guiding holes, where the probes requiring impedance matching (i.e. the first probe and the second probe) are located, and/or the outer diameters of the probes can be adjusted for different impedance matching requirements, so as to adjust the air volume and the wall thickness of the middle die located between the first and second probes, and the inductance of the first and second probes. Compared with the situation without the above-described adjustment, as long as the first difference is larger than or equal to 10 μm, and/or the second difference is larger than or equal to 10 μm, and/or the third difference is larger than or equal to 5 μm, the first and second probes is provided with raised impedance therebetween. The above-described adjustment performed under this condition can fine adjust the impedance to satisfy the requirement of impedance matching.

Preferably, the first probe is adapted to transmit a test signal. The second probe is adapted to transmit a ground signal. The probe head includes a plurality of second probes and a plurality of second middle guiding holes accommodating the second probes respectively, thereby defined with a plurality of second differences. Each second probe has a pitch from the first probe. The pitches of the plurality of second probes from the first probe are unequal to each other. At least one of the first difference and the plurality of second differences is larger than or equal to 10 μm.

As a result, the first probe is a signal probe, which is located adjacent to a plurality of ground probes (i.e. the second probes) with different pitches therebetween. The impedance matching between the first and second probes in this arrangement is also attainable by the adjustment of the outer diameters of the first and second probes and/or the widths of the middle guiding holes where they are located. Compared with the situation without the above-described adjustment, as long as at least one of the first and second differences is larger than or equal to 10 μm, the first and second probes is provided with raised impedance therebetween. The above-described adjustment performed under this condition can fine adjust the impedance to satisfy the requirement of impedance matching.

Preferably, the first probe is adapted to transmit a first test signal. The second probe is adapted to transmit a second test signal. The probe head includes a plurality of second probes and a plurality of second middle guiding holes accommodating the second probes respectively, thereby defined with a plurality of second differences. Each second probe has a pitch from the first probe. The pitches of the plurality of second probes from the first probe are unequal to each other. At least one of the first difference and the plurality of second differences is larger than or equal to 10 μm.

As a result, the first and second probes are all signal probes, but the first probe and the second probes may transmit the same or different test signals. The first probe is located adjacent to a plurality of second probes with different pitches therebetween. The impedance matching between the first and second probes in this arrangement is also attainable by the adjustment of the outer diameters of the first and second probes and/or the widths of the middle guiding holes where they are located. Compared with the situation without the above-described adjustment, as long as at least one of the first and second differences is larger than or equal to 10 μm, the first and second probes is provided with raised impedance therebetween. The above-described adjustment performed under this condition can fine adjust the impedance to satisfy the requirement of impedance matching.

Preferably, the above-described adjustment may make the first difference and/or the second difference not only larger than or equal to 10 micrometers but larger than or equal to 12 micrometers, and/or the third difference not only larger than or equal to 5 micrometers but larger than or equal to 7 micrometers, for ensuring that the impedance between the first and second probes is obviously raised by the adjustment, so as to obtain the required impedance matching property by the adjustment under this condition.

More preferably, the above-described adjustment may make the first difference and/or the second difference not only larger than or equal to 12 micrometers but larger than or equal to 14 micrometers, and/or the third difference not only larger than or equal to 7 micrometers but larger than or equal to 10 micrometers, for ensuring that the impedance between the first and second probes is raised relatively more obviously by the adjustment, so as to obtain the required impedance matching property by the adjustment under this condition.

To attain the above objective, the present invention further provides another probe head having spring probes, which includes an upper die, a lower die, a middle die disposed between the upper die and the lower die, and a plurality of spring probes. The upper die includes a plurality of upper guiding holes. The lower die includes a plurality of lower guiding holes. The middle die includes a plurality of middle guiding holes. The spring probes each include an upper abutting section, a lower abutting section, a spring section connecting the upper abutting section and the lower abutting section, and a barrel disposed on the periphery of the spring section. The upper abutting sections of the spring probes are inserted in the upper guiding holes respectively. The lower abutting sections of the spring probes are inserted in the lower guiding holes respectively. The barrels of the spring probes are disposed in the middle guiding holes of the middle die. The barrel of each spring probe has an outer diameter. The plurality of middle guiding holes include a multi-probe matching hole. The barrels of a plurality of spring probes are located in the multi-probe matching hole. The outer diameters of two adjacent barrels located in the multi-probe matching hole are larger than the smallest distance between the aforementioned two adjacent barrels.

As a result, the spring probes in the above-described probe head are also normal non-coaxial spring probes, and able to be manufactured with the required outer diameter according to the test requirement, thereby capable of satisfying the test requirement of fine pitch. However, the spring probes in the above-described probe head are not disposed in the middle guiding holes of the middle die in a one-to-one manner, but have the condition that a plurality of spring probes are disposed in the same middle guiding hole (i.e. the multi-probe matching hole). Although there is only air between the barrels of the adjacent spring probes located in the multi-probe matching hole, compared with such case without middle die as described in the description of the related art, the middle die in this probe head can still bring the effect of lowering the impedance. Besides, the outer diameters of the barrels of the spring probes located in the multi-probe matching hole and requiring impedance matching can be adjusted for different impedance matching requirements, so as to adjust the capacitance therebetween and their own inductance. Because the pitch between the adjacent spring probes should be matched with the device under test and thereby unadjustable, the smallest distance between the adjacent barrels will be decreased by the increase of the outer diameter of the barrel of the spring probe. As long as the outer diameter of the barrel of the spring probe is adjusted under the condition that the outer diameters of the barrels of two adjacent spring probes located in the multi-probe matching hole and requiring impedance matching (that means there can be only a pair of spring probes satisfying this condition) are larger than the smallest distance therebetween, the impedance can be fine adjusted to satisfy the requirement of impedance matching.

Preferably, the plurality of spring probes include a first probe for transmitting a test signal, and a plurality of second probes located adjacent to the first probe for transmitting a ground signal. Each second probe has a pitch from the first probe. The pitches of the plurality of second probes from the first probe are unequal to each other. The barrel of the first probe and the barrel of at least one second probe are located in the multi-probe matching hole.

As a result, the first probe is a signal probe, which is located adjacent to a plurality of ground probes (i.e. the second probes) with different pitches therebetween. The impedance matching between the first and second probes in this arrangement is also attainable by the disposal of the first probe and at least one second probe in the same middle guiding hole (i.e. the multi-probe matching hole) and the adjustment of the outer diameters of the first and second probes.

Preferably, the plurality of spring probes include a first probe for transmitting a first test signal, and a plurality of second probes located adjacent to the first probe for transmitting a second test signal. Each second probe has a pitch from the first probe. The pitches of the plurality of second probes from the first probe are unequal to each other. The barrel of the first probe and the barrel of at least one second probe are located in the multi-probe matching hole.

As a result, the first and second probes are all signal probes, but the first probe and the second probes may transmit the same or different test signals. The first probe is located adjacent to a plurality of second probes with different pitches therebetween. The impedance matching between the first and second probes in this arrangement is also attainable by the disposal of the first probe and at least one second probe in the same middle guiding hole (i.e. the multi-probe matching hole) and the adjustment of the outer diameters of the first and second probes.

Preferably, the plurality of middle guiding holes further include a single probe matching hole located adjacent to the multi-probe matching hole. The barrel of a spring probe is inserted in the single probe matching hole. The difference between a width of the single probe matching hole and an outer diameter of the barrel accommodated therein is larger than or equal to 10 μm.

As a result, in addition to the adjustment of the outer diameters of the barrels of two adjacent spring probes located in the multi-probe matching hole, the width of other middle guiding hole (i.e. single probe matching hole) for the barrel of only one spring probe to be inserted therein and/or the outer diameter of the barrel of the spring probe accommodated therein can be also adjusted at the same time, so as to adjust the impedance between the spring probe located in the single probe matching hole and the spring probe located in the multi-probe matching hole. Compared with the situation without the above-described adjustment, as long as the difference between the width of the single probe matching hole and the outer diameter of the barrel accommodated therein is larger than or equal to 10 μm, the spring probe located in the single probe matching hole and the spring probe located in the multi-probe matching hole are provided with raised impedance therebetween. The above-described adjustment performed under this condition can fine adjust the impedance to satisfy the requirement of impedance matching.

No matter the spring probes are disposed in the middle guiding holes of the middle die in a one-to-one manner, or there is the situation that a plurality of spring probes are disposed in the multi-probe matching hole, the spring probes are disposed in the lower guiding holes of the lower die in a one-to-one manner. Each lower guiding hole may only have a single bore diameter (corresponding to the diameter of the lower abutting section). Alternatively, each lower guiding hole may be preferably stair-shaped, thereby having a relatively wider portion and a relatively narrower portion. The barrel of each spring probe is partially located in the relatively wider portion. The lower abutting section of each spring probe is inserted in the relatively narrower portion.

As a result, in the above-described case that the lower guiding hole is stair-shaped, not only the relatively narrower portion of the lower guiding hole can be provided correspondingly to the diameter of the lower abutting section to attain the effect of guiding and maintaining the position of the lower abutting section, but the relatively wider portion of the lower guiding hole can be also provided correspondingly to the outer diameter of the barrel to attain the effect of guiding and maintaining the position of the barrel. In this way, the relative position between the barrel and the middle guiding hole where it is located and the relative position between the barrels of the adjacent spring probes can be further ensured, making the impedance matching effect relatively more stable.

Preferably, the probe head further includes an insulating positioning film. The insulating positioning film is located between the upper die and the lower die. The insulating positioning film includes a plurality of positioning holes. The barrels of the spring probes are inserted in the positioning holes respectively. The difference between a width of each positioning hole and an outer diameter of the barrel accommodated therein is smaller than 10 micrometers. As a result, the positioning holes of the insulating positioning film can bring the effect of positioning the spring probes to facilitate the probe installation process.

More preferably, the insulating positioning film is provided thereon with a circuit electrically connected with the spring probe. As a result, the insulating positioning film not only can bring the effect of positioning the spring probes, but also can transmit the test signal or power together with the spring probe.

More preferably, the insulating positioning film is made of wave absorbing material. As a result, the insulating positioning film can further prevent the signals of the spring probes from interference with each other.

The detailed structure, features, assembly or usage of the probe head having spring probes provided by the present invention will be described in the following detailed description of embodiments. However, those skilled in the field of the present invention should understand that the detailed descriptions and specific embodiments instanced for implementing the present invention are given by way of illustration only, not intended to limit the scope of the claims of the present invention.

### BRIEF DESCRIPTION OF THE DRAWINGS

FIG. 1 is a schematic sectional view of a conventional probe head having spring probes.

FIG. 2 is a schematic sectional view of a probe head having spring probes according to a first preferred embodiment of the present invention.

FIG. 3 is a schematic sectional view of a middle die and two spring probes of the probe head having spring probes according to the first preferred embodiment of the present invention.

FIG. 4 is a schematic sectional view of a probe head having spring probes according to a second preferred embodiment of the present invention.

FIG. 5 is a schematic sectional view of a middle die and two spring probes of the probe head having spring probes according to the second preferred embodiment of the present invention.

FIG. 6 is a schematic sectional view of a probe head having spring probes according to a third preferred embodiment of the present invention.

FIG. 7 is a schematic sectional view of a middle die and two spring probes of the probe head having spring probes according to the third preferred embodiment of the present invention.

FIG. 8 is a schematic sectional view of a probe head having spring probes according to a fourth preferred embodiment of the present invention.

FIG. 9 is a schematic sectional view of a middle die and two spring probes of the probe head having spring probes according to the fourth preferred embodiment of the present invention.

FIG. 10a is similar to FIG. 3, but showing an arrangement including three spring probes.

FIG. 10b to FIG. 10e are similar to FIG. 10a, but showing four arrangements including a multi-probe matching hole.

FIG. 11a is similar to FIG. 10a, but showing an arrangement including four spring probes.

FIG. 11b to FIG. 11d are similar to FIG. 11a, but showing three arrangements including a multi-probe matching hole.

FIG. 12 is a schematic sectional view of a probe head having spring probes according to a fifth preferred embodiment of the present invention.

FIG. 13 is a schematic sectional view of a probe head having spring probes according to a sixth preferred embodiment of the present invention, and a circuit board and a circuit film are further shown therein.

FIG. 14 is a schematic sectional view showing the application of the probe head provided by the present invention to after-encapsulation IC final test.

### DETAILED DESCRIPTION OF THE INVENTION

First of all, it is to be mentioned that same reference numerals used in the following embodiments and the appendix drawings designate same or similar elements or the structural features thereof. It should be noticed that for the convenience of illustration, the components and the structure shown in the figures are not drawn according to the real scale and amount, and the features mentioned in each embodiment can be applied in the other embodiments if the application is possible in practice. Besides, when it is mentioned that an element is disposed on another element, it means that the former element is directly disposed on the latter element, or the former element is indirectly disposed on the latter element through one or more other elements between aforesaid former and latter elements. When it is mentioned that an element is directly disposed on another element, it means that no other element is disposed between aforesaid former and latter elements.

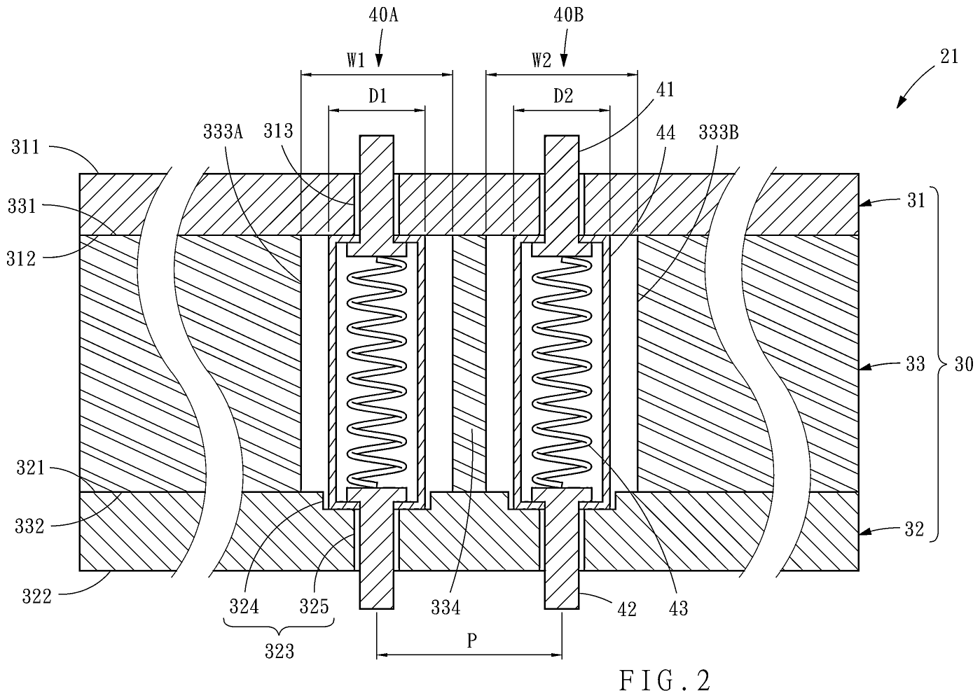

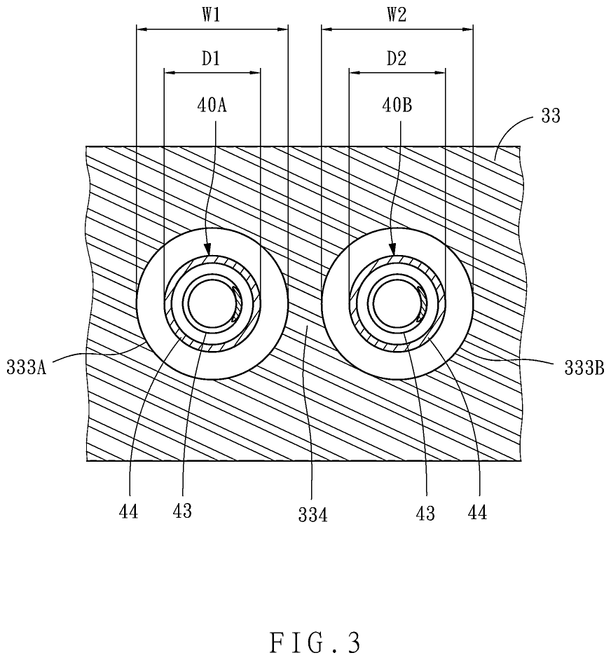

Referring to FIG. 2 and FIG. 3, a probe head 21 according to a first preferred embodiment of the present invention includes a probe seat 30, and a plurality of spring probes 40A, 40B inserted in the probe seat 30.

The probe seat 30 includes an upper die 31, a lower die 32, and a middle die 33 disposed between the upper die 31 and the lower die 32. The upper die 31 has an upper surface 311, a lower surface 312, and a plurality of upper guiding holes 313 penetrating through the upper surface 311 and the lower surface 312. The lower die 32 has an upper surface 321, a lower surface 322, and a plurality of lower guiding holes 323 penetrating through the upper surface 321 and the lower surface 322. Each lower guiding hole 323 may (but unlimited to) be stair-shaped, thereby having a relatively wider portion 324 and a relatively narrower portion 325. The middle die 33 has an upper surface 331, a lower surface 332, and a plurality of middle guiding holes 333A, 333B penetrating through the upper surface 331 and the lower surface 332. The upper surface 331 of the middle die 33 is fixedly connected to the lower surface 312 of the upper die 31, and the middle guiding holes 333A, 333B coaxially correspond to the upper guiding holes 313 respectively. The upper surface 321 of the lower die 32 is fixedly connected to the lower surface 332 of the middle die 33, and the lower guiding holes 323 coaxially correspond to the middle guiding holes 333A, 333B respectively. However, the middle guiding holes 333A, 333B are unlimited to coaxially correspond to the upper and lower guiding holes 313, 323. Under the condition of the allowance of the hole position arrangement of the middle die 33, the middle guiding holes 333A, 333B may be not coaxial with the upper and lower guiding holes 313, 323, as long as the upper and lower guiding holes 313, 323 are coaxial and the vertical projection areas of the upper and lower guiding holes 313, 323 correspond to the middle guiding holes 333A, 333B.

The spring probes 40A, 40B each include an upper abutting section 41, a lower abutting section 42, a spring section 43 connecting the upper abutting section 41 and the lower abutting section 42, and a barrel 44 disposed on the periphery of the spring section 43. The upper abutting section 41 and the lower abutting section 42 protrude out of the top surface and the bottom surface of the barrel 44 respectively, and can receive force to retract into the barrel 44 to compress the spring section 43. The upper abutting sections 41 of the spring probes 40A, 40B are inserted in the upper guiding holes 313 respectively for being abutted against electrically conductive contacts on the bottom surface of a space transformer or circuit board (not shown) disposed above the upper die 31. The lower abutting sections 42 of the spring probes 40A, 40B are inserted in the relatively narrower portions 325 of the lower guiding holes 323 respectively for contacting electrically conductive contacts on the top surface of a device under test (not shown) located below the lower die 32. The barrels 44 of the spring probes 40A, 40B are primarily inserted in the middle guiding holes 333A, 333B respectively, but in this embodiment, the bottom of the barrel 44 of each of the spring probes 40A, 40B is located in the relatively wider portion 324 of the lower guiding hole 323.

The probe head of the present invention includes many spring probes in practice. For the simplification of the figures and the convenience of illustration, in each figure of the present invention, only a few spring probes required for the illustration of the technical features of the present invention and the corresponding upper, middle and lower guiding holes are shown. In this embodiment, the spring probes of the probe head 21 include a first probe 40A and a second probe 40B, which are located adjacent to each other. The middle guiding holes of the middle die 33 include a first middle guiding hole 333A and a second middle guiding hole 333B, which accommodate the first and second probes 40A, 40B respectively.

The upper, middle and lower dies 31, 33, 32 may be all made of non-conductive material for preventing the coefficient of thermal expansion (also called CTE for short) thereof from being so large as to result in that during the high-temperature or low-temperature test, the extent of the thermal expansion of the upper, middle and lower dies 31, 33, 32 is so large as to cause the upper, middle and lower guiding holes to displace, thereby make the spring probes deviate from the predetermined positions thereof. The upper, middle and lower dies 31, 33, 32 may be even made of the materials with the same CTE for further ensuring that the thermal expansion of the upper, middle and lower dies 31, 33, 32 will not make the spring probes deviate from the predetermined positions thereof.

Besides, the upper, middle and lower dies 31, 33, 32 may be made of the same material or different materials substantially the same in dielectric constant. The dielectric constant of the material of the upper, middle and lower dies 31, 33, 32 is larger than 1. The measured value of the dielectric constant is related to the testing method, testing frequency, the size of the device under test, the testing environment, and so on. Therefore, the substantially the same dielectric constant mentioned in the present invention is defined in a way that the deviation between the measured values in the dielectric constant test is smaller than 20%. However, the bore diameter of the upper guiding hole 313 can be only slightly larger than the diameter of the upper abutting section 41, and the bore diameter of the relatively narrower portion 325 of the lower guiding hole 323 can be only slightly larger than the diameter of the lower abutting section 42, for bringing the effect of guiding and maintaining the positions of the upper and lower abutting sections 41, 42, so as to ensure that the upper abutting section 41 can be accurately abutted against the electrically conductive contact of the space transformer or circuit board, and ensure that the lower abutting section 42 can accurately contact the electrically conductive contact of the device under test. Therefore, the bore diameters of the upper and lower guiding holes 313, 323 cannot be adjusted at will, which limits the impedance matching property of the upper and lower abutting sections 41, 42. Under this consideration, the upper, middle and lower dies 31, 33, 32 may be made of materials different in dielectric constant, so that the required impedance of the upper and lower abutting sections 41, 42 can be obtained by the adjustment of changing the materials of the upper and lower dies 31, 32. Further speaking, because the diameters of the upper and lower abutting sections 41, 42 are smaller than the outer diameter of the barrel 44, the inductance values of the upper and lower abutting sections 41, 42 are larger than the inductance value of the barrel 44. In the condition that the upper, middle and lower dies 31, 33, 32 are the same in dielectric constant and the barrel 44 attains the goal impedance value, the impedance of the upper and lower abutting sections 41, 42 will be higher than the goal impedance value. Therefore, the dielectric constant of the upper and lower dies 31, 32 is preferably higher than the dielectric constant of the middle die 33 for raising the capacitance between the upper abutting sections 41 and the capacitance between the lower abutting sections 42, so as to lower the impedance of the upper and lower abutting sections 41, 42 to the goal impedance value to make the upper and lower abutting sections 41, 42 attain impedance matching. In some cases, the length, for which the lower abutting section 42 protrudes out of the barrel 44, is larger than the length, for which the upper abutting section 41 protrudes out of the barrel 44, such that the inductance value of the lower abutting section 42 is larger than the inductance value of the upper abutting section 41. In such case, the dielectric constant of the lower die 32 may be provided larger than the dielectric constant of the upper die 31 to make the decrease of the impedance of the lower abutting section 42 more than that of the impedance of the upper abutting section 41, so as to make the upper and lower abutting sections 41, 42 bott attain the goal impedance value. Summarizing each above-described case, the dielectric constant of the lower die 32 is larger than or equal to the dielectric constant of the upper die 31, and the dielectric constant of the upper die 31 is larger than or equal to the dielectric constant of the middle die 33.

In this embodiment, the barrel 44 of the first probe 40A and the barrel 44 of the second probe 40B have a first outer diameter D1 and a second outer diameter D2 respectively. The first and second outer diameters D1, D2 are equal. The first middle guiding hole 333A and the second middle guiding hole 333B have a first width W1 and a second width W2 respectively. The first and second widths W1, W2 are equal. As shown in FIG. 3, the first and second middle guiding holes 333A, 333B in this embodiment are circular in horizontal cross-sectional shape, so the first and second widths W1, W2 are the diameters of the first and second middle guiding holes 333A, 333B. However, the horizontal cross-sectional shape of the middle guiding hole in the present invention is unlimited, and the width thereof refers to the length of the shortest imaginary line passing through the center thereof and having two ends located on the edges thereof. For example, the middle guiding hole may be rectangular in horizontal cross-sectional shape, such that the width thereof is equal to the length of the short edge. Alternatively, the middle guiding hole may be oval in horizontal cross-sectional shape, such that the width thereof is equal to the length of the short axis. Furthermore, the width of the middle guiding hole having other cross-sectional shapes may be deduced by analogy.

As shown in FIG. 2, the pitch P between the adjacent spring probes 40A, 40B should be matched with the pitch between the electrically conductive contacts of the device under test, and the sum of the first outer diameter D1 and the second outer diameter D2 should be smaller than twice the pitch P (i.e. D1+D2<2P), such that the first and second probes 40A, 40B can be installed in the probe seat 30 separately from each other. When the required pitch P is very small, the first and second probes 40A, 40B should be manufactured being thin enough to satisfy the condition of D1+D2<2P. It can be known from the above description that the spring probes 40A, 40B in the present invention are normal non-coaxial spring probes, able to be manufactured with the required outer diameter according to the test requirement, thereby capable of satisfying the test requirement of fine pitch (for example, the pitch P is smaller than 500 μm).

It deserves to be mentioned that the middle die is unlimited to be composed of a single board as shown in this embodiment, but may be composed of two or even more piled boards. Under the test requirement of fine pitch, the width of the middle guiding hole is also very small, so the aspect ratio of the middle guiding hole may be larger than the aspect ratio attainable by the drilling processing performed to a single board. Such case should adopt the middle die composed of a plurality of boards, so that the different boards are drilled separately and then the middle guiding holes with large aspect ratio will be formed when the boards are connected with each other.

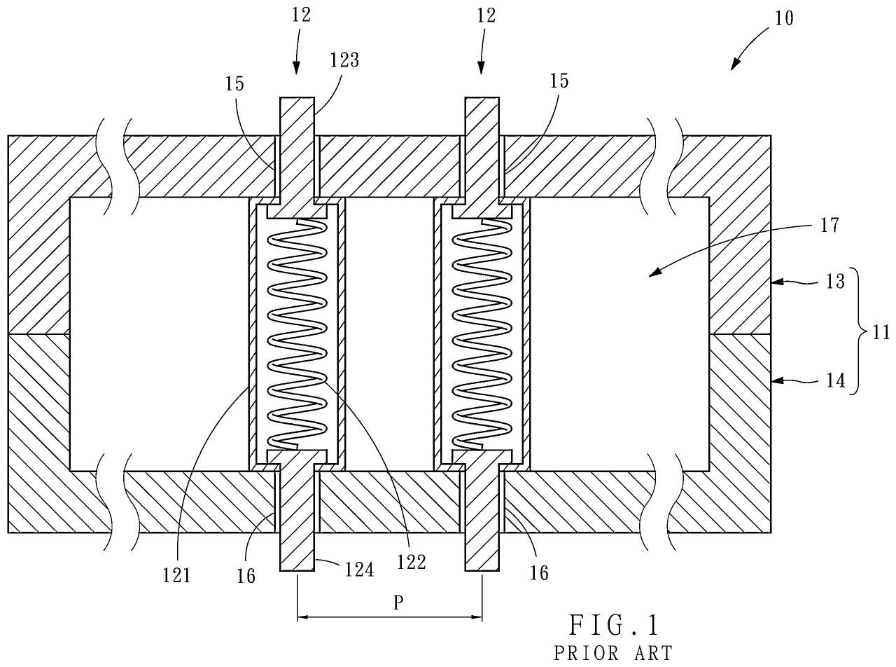

In this embodiment, the spring probes 40A, 40B are disposed in the middle guiding holes 333A, 333B of the middle die 33 in a one-to-one manner, so that not only the air located in the middle guiding holes 333A, 333B but also a partition portion 334 of the middle die 33 (i.e. the partial middle die 33 located between the middle guiding holes 333A, 333B) exist between the barrels 44 of the spring probes 40A, 40B. Compared with such case without middle die as described in the description of the related art (as shown in FIG. 1), the middle die 33 in the present invention will cause raised capacitance value and lowered impedance between the adjacent barrels 44. In order to prevent the capacitance value from being so high as to result in that the impedance is slightly lower than the expected value, the first and second widths W1, W2 of the first and second middle guiding holes 333A, 333B are further adjusted in this embodiment.

It should be mentioned here that the situation without adjustment mentioned in the present invention refers to that the first and second widths W1, W2 of the first and second middle guiding holes 333A, 333B are only slightly larger than the first and second outer diameters D1, D2 of the barrels 44 accommodated therein, so that the first and second middle guiding holes 333A, 333B can bring the effect of guiding and maintaining the positions of the barrels 44 (this kind of middle guiding hole is also called guidance hole hereinafter). Generally speaking, the width of the guidance hole and the outer diameter of the barrel are almost equal, but only have quite tiny tolerance. The above-described adjustment is making the first and second middle guiding holes 333A, 333B larger than those in the situation without adjustment, so that the first and second widths W1, W2 are at least 10 μm larger than the first and second outer diameters D1, D2. Although such first and second middle guiding holes 333A, 333B have no effect of guiding and maintaining the positions of the barrels 44, the adjustment of the first and second widths W1, W2 can adjust the impedance between the barrels 44 of the first and second probes 40A, 40B to satisfy different impedance matching requirements (this kind of middle guiding hole is also called matching hole hereinafter).

Specifically speaking, the difference between the first width W1 and the first outer diameter D1 is defined as a first difference (i.e. W1−D1), the difference between the second width W2 and the second outer diameter D2 is defined as a second difference (i.e. W2−D2), and at least one of the first difference and the second difference is larger than or equal to 10 nm. It can be thus known that although the first and second middle guiding holes 333A, 333B in this embodiment are both matching holes, according to different impedance matching requirements, the matching hole may be only the first middle guiding hole 333A or the second middle guiding hole 333B, but the other one is the guidance hole. The adjustment of the first width W1 and/or the second width W2 can adjust the air volume and the thickness of the partition portion 334 located between the first and second probes 40A, 40B, so as to raise the impedance between the first and second probes 40A, 40B (compared with the above-described situation without adjustment) to satisfy the requirement of impedance matching.

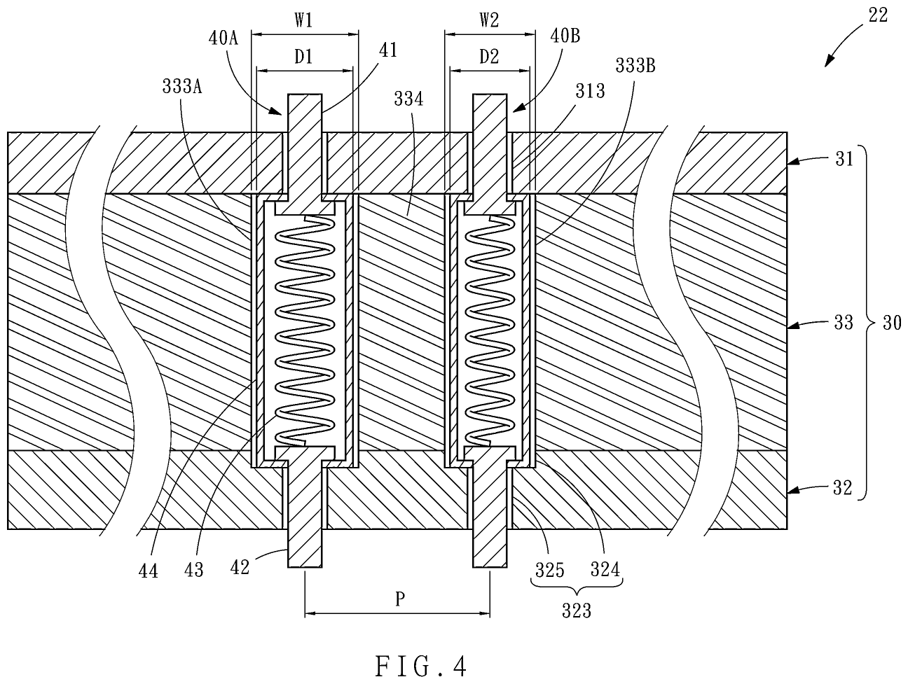

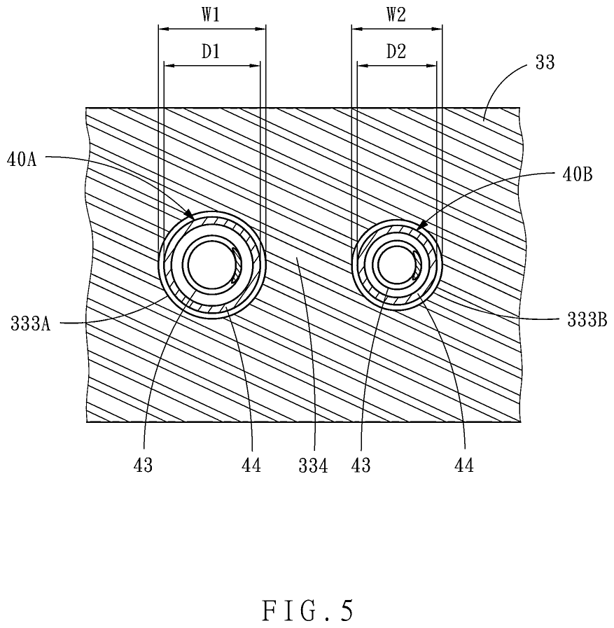

Referring to FIG. 4 and FIG. 5, a probe head 22 according to a second preferred embodiment of the present invention is similar to the above-described probe head 21, but the primary difference therebetween lies in that the first outer diameter D1 of the first probe 40A is larger than the second outer diameter D2 of the second probe 40B, the difference between the first outer diameter D1 and the second outer diameter D2 is defined as a third difference (i.e. D1−D2), and the third difference is larger than or equal to 5 μm. Besides, the first and second widths W1, W2 of the first and second middle guiding holes 333A, 333B are only slightly larger than the first and second outer diameters D1 D2 respectively, which means the first and second middle guiding holes 333A, 333B are both guidance holes. Under the structure of this embodiment, the adjustment of the first outer diameter D1 and the second outer diameter D2 (the first and second widths W1, W2 are provided according to the first and second outer diameters D1, D2) can adjust the thickness of the partition portion 334 located between the first and second probes 40A, 40B and the inductance values of the first and second probes 40A, 40B to make the first and second probes 40A, 40B satisfy the requirement of impedance matching.

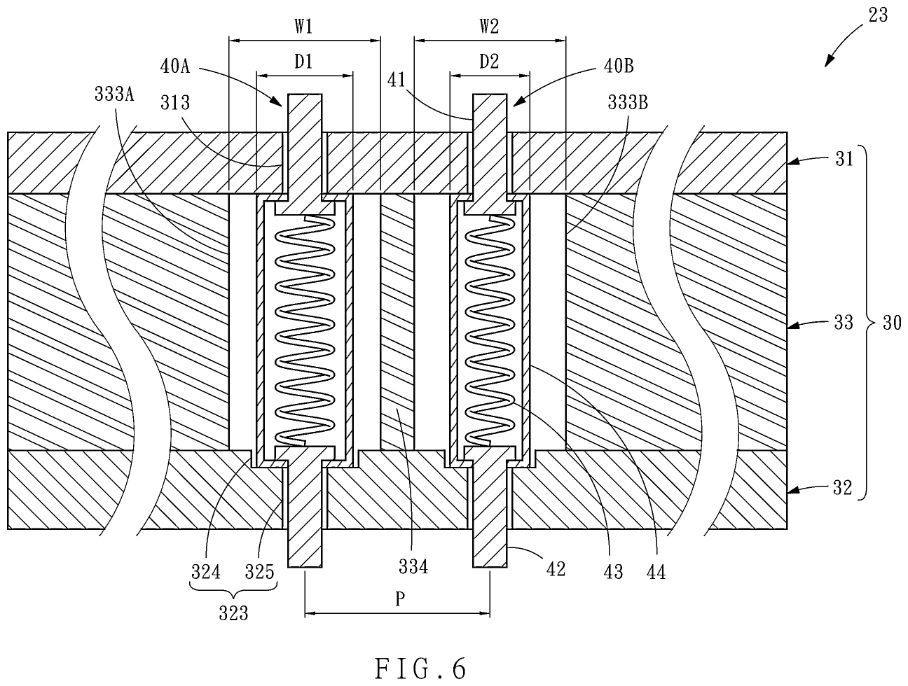

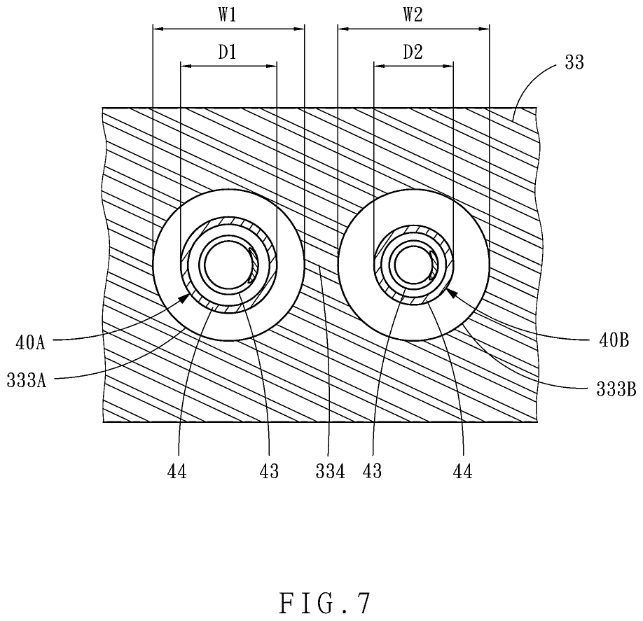

Referring to FIG. 6 and FIG. 7, a probe head 23 according to a third preferred embodiment of the present invention is similar to the above-described probe head 22, but the primary difference therebetween lies in that the first and second middle guiding holes 333A, 333B are both matching holes, which means they satisfy the condition mentioned in the first preferred embodiment that the first difference (i.e. W1−D1) and the second difference (i.e. W2−D2) are larger than or equal to 10 μm. According to different impedance matching requirements, the matching hole may be only the first middle guiding hole 333A or the second middle guiding hole 333B, but the other one is the guidance hole. Under the structure of this embodiment, the adjustment of the first and second outer diameters D1, D2 and the first and second widths W1, W2 can adjust the air volume and the thickness of the partition portion 334 located between the first and second probes 40A, 40B and the inductance values of the first and second probes 40A, 40B to make the first and second probes 40A, 40B satisfy the requirement of impedance matching.

Summarizing the above cases, as long as the first and second outer diameters D1, D2 of the first and second probes 40A, 40B and/or the first and second widths W1, W2 of the first and second middle guiding holes 333A, 333B are adjusted under the condition that the first difference (i.e. W1−D1) is larger than or equal to 10 μm, and/or the second difference (i.e. W2−D2) is larger than or equal to 10 μm, and/or the third difference (i.e. D1−D2) is larger than or equal to 5 μm, the impedance between the first and second probes 40A, 40B can be fine adjusted to satisfy different impedance matching requirements. Preferably, the above-described adjustment may make the first difference and/or the second difference not only larger than or equal to 10 micrometers but larger than or equal to 12 micrometers, and/or the third difference not only larger than or equal to 5 micrometers but larger than or equal to 7 micrometers, for ensuring that the impedance between the first and second probes 40A, 40B is obviously raised by the adjustment, so as to obtain the required impedance matching property by the adjustment under this condition. More preferably, the above-described adjustment may make the first difference and/or the second difference not only larger than or equal to 12 micrometers but larger than or equal to 14 micrometers, and/or the third difference not only larger than or equal to 7 micrometers but larger than or equal to 10 micrometers, for ensuring that the impedance between the first and second probes 40A, 40B is raised relatively more obviously by the adjustment, so as to obtain the required impedance matching property by the adjustment under this condition.

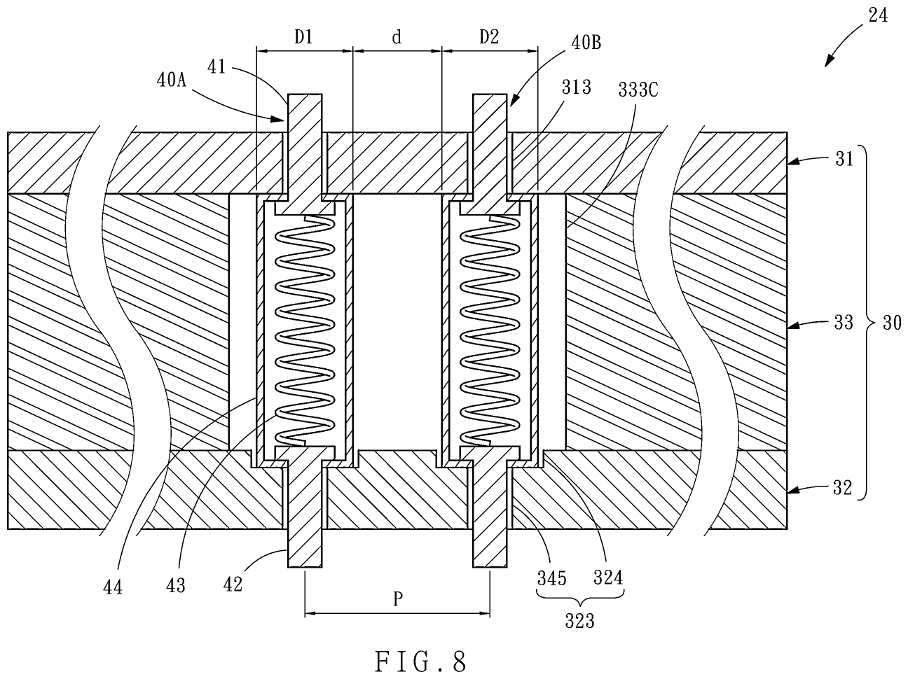

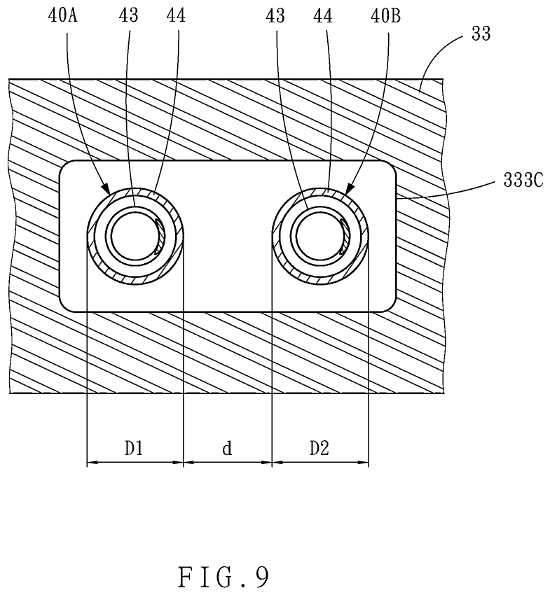

Referring to FIG. 8 and FIG. 9, a probe head 24 according to a fourth preferred embodiment of the present invention is similar to the above-described probe head 21 (as shown in FIG. 2 and FIG. 3), but the primary difference therebetween lies in that the spring probes in the probe head 24 of this embodiment are not disposed in the middle guiding holes of the middle die 33 in a one-to-one manner, but have the condition that a plurality of spring probes are disposed in the same middle guiding hole. Specifically speaking, in this embodiment, the middle guiding holes of the middle die 33 include a multi-probe matching hole 333C. The barrels 44 of a plurality of spring probes 40A, 40B are located in the multi-probe matching hole 333C.

Although there is only air between the barrels 44 of the adjacent spring probes 40A, 40B in the multi-probe matching hole 333C, compared with such case without middle die as described in the description of the related art (as shown in FIG. 1), the middle die 33 in this probe head 24 can still bring the effect of lowering the impedance. Besides, the outer diameters of the barrels 44 of the spring probes 40A, 40B (i.e. the first and second outer diameters D1, D2) located in the multi-probe matching hole 333C and requiring impedance matching can be adjusted for different impedance matching requirements, so as to adjust the capacitance between the barrels 44 of the spring probes 40A, 40B and their own inductances.

The adjacent spring probes 40A, 40B have a pitch P and a smallest distance d (i.e. the smallest distance between the adjacent barrels 44) therebetween, and d=P−(½)(D1+D2). Because the pitch P should be matched with the device under test and thereby unadjustable, the smallest distance d will be decreased by the increase of the first outer diameter D1 and/or the second outer diameter D2, which will cause increased capacitance and decreased impedance between the spring probes 40A, 40B. Under the structure of this embodiment, as long as the adjustment of the outer diameters D1, D2 of the barrels of the spring probes 40A, 40B is performed under the condition that the outer diameters of two adjacent barrels 44 located in the multi-probe matching hole 333C (that means there can be only a pair of spring probes satisfying this condition) are larger than the smallest distance therebetween (i.e. D1>d, D2>d), the impedance between the spring probes 40A, 40B can be fine adjusted to satisfy the requirement of impedance matching.

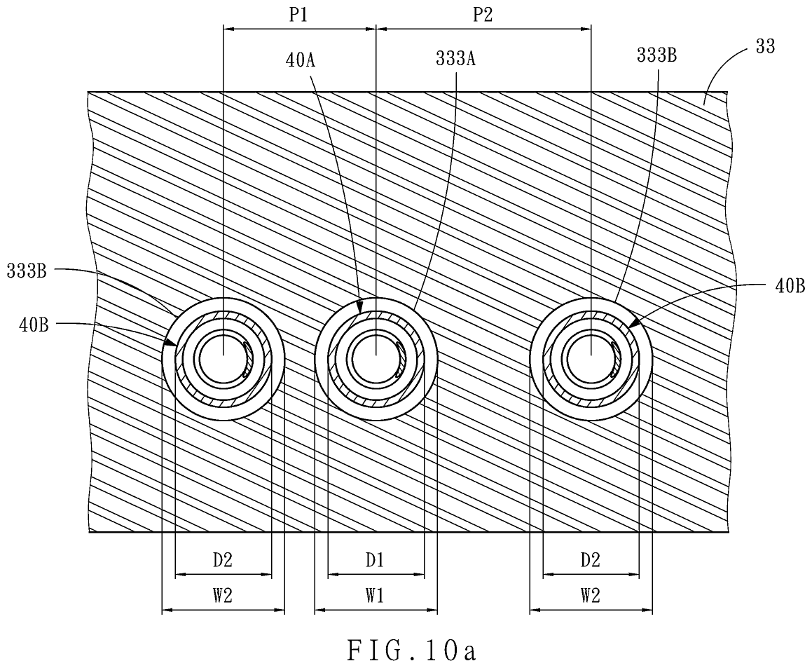

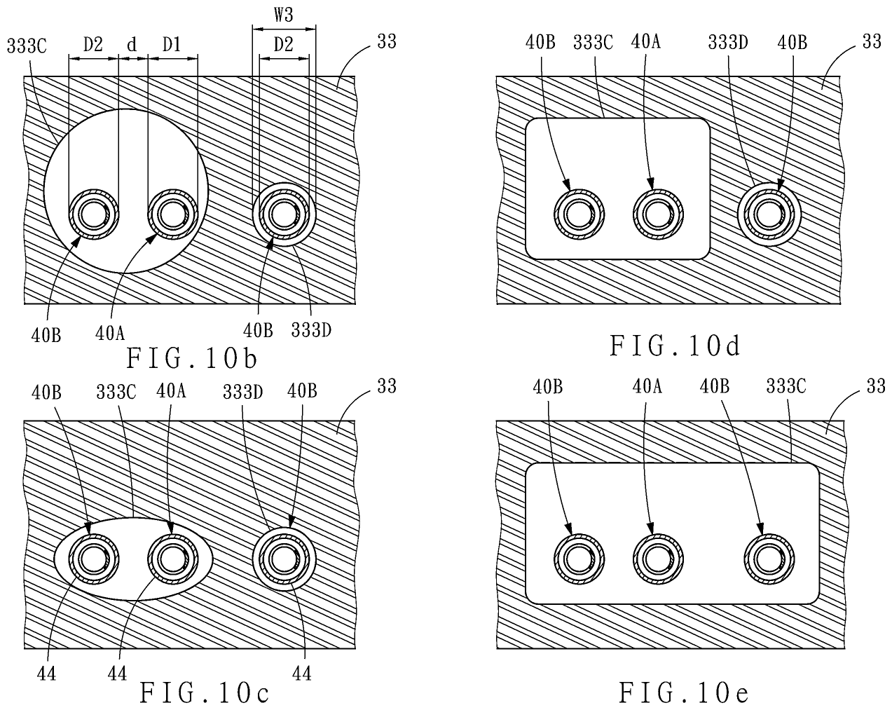

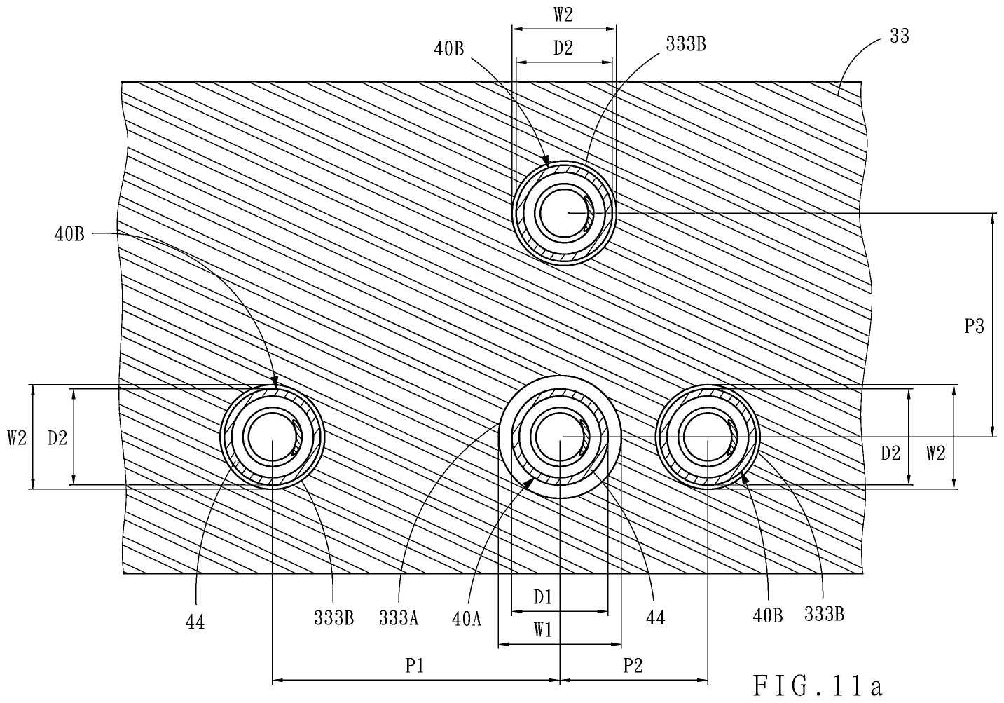

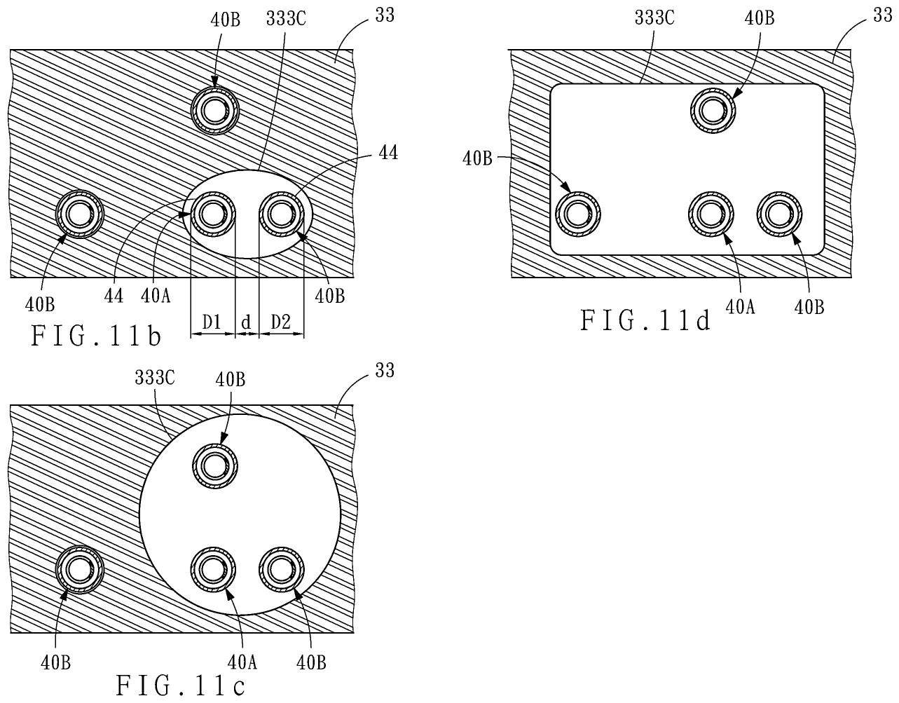

In each of the above-described embodiments, the spring probes 40A, 40B may be a signal probe for transmitting a test signal and a ground probe for transmitting a ground signal respectively, so that the impedance matching between the signal probe and the ground probe is performed. Alternatively, the spring probes 40A, 40B may be both signal probes for transmitting a first test signal and a second test signal respectively. The first and second test signals may be different test signals (such as differential signal pair) or may be the same test signal, so that the impedance matching between the signal probes is performed. Alternatively, the impedance matching may be performed between more than two spring probes 40A, 40B in the present invention, such as that shown in FIG. 10a to FIG. 10e and FIG. 11a to FIG. 11d, which will be described in detail hereinafter.

The middle die 33 of the probe head, and a first probe 40A and two second probes 40B, which require impedance matching, are shown in FIG. 10a to FIG. 10e. The first probe 40A is adapted to transmit a first test signal. The second probe 40B is adapted to transmit a second test signal. The arrangements of the first and second probes 40A, 40B shown in FIG. 10a to FIG. 10e are completely the same, but the arrangements of the middle guiding hole are different. As shown in FIG. 10a, the pitches P1, P2 of two second probes 40B from the first probe 40A are unequal.

In FIG. 10a, the first and second probes 40A, 40B are disposed in the first and second middle guiding holes 333A, 333B of the middle die 33 in a one-to-one manner, similar to the above-described cases of the first to third preferred embodiments, thereby defined with a first difference (i.e. W1−D1) and two second differences (i.e. W2−D2). In this arrangement, the first and second outer diameters D1, D2 of the first and second probes 40A, 40B and/or the first and second widths W1, W2 of the first and second middle guiding holes 333A, 333B can be adjusted under the condition that at least one of the first and second differences is larger than or equal to 10 μm (that means at least one of the first and second middle guiding holes 333A, 333B is the matching hole, and for example, the three shown in FIG. 10a are all matching holes), such that the impedance between the first and second probes 40A, 40B can be fine adjusted to satisfy the requirement of impedance matching.

In FIG. 10b to FIG. 10e, the barrel 44 of the first probe 40A and the barrel 44 of at least one second probe 40B are located in a multi-probe matching hole 333C. In the present invention, the shape of the multi-probe matching hole 333C is unlimited, which may be a circle, oval, rectangle, and so on, and can be designed according to the requirement. FIG. 10b to FIG. 10e are similar to the above-described case of the fourth preferred embodiment, wherein the adjustment of the outer diameters D1, D2 of the barrels of the spring probes 40A, 40B can be performed under the condition that the outer diameters of two adjacent barrels 44 located in the multi-probe matching hole 333C are larger than the smallest distance therebetween (i.e. D1>d, D2>d, as shown in FIG. 10b), such that the impedance between the first and second probes 40A, 40B can be fine adjusted to satisfy the requirement of impedance matching. It can be known from FIG. 10e that in the case that more than two spring probes are disposed in the multi-probe matching hole 333C, there can be only two adjacent spring probes of them satisfying the condition that the outer diameters of their barrels are larger than the smallest distance therebetween. For example, this condition is satisfied only between the left second probe 40B and the first probe 40A in FIG. 10e. Further speaking, a set of first and second probes 40A, 40B will be chosen as the primarily adjusted set. The rest of the first and second probes 40A, 40B, or the first probe 40A and the rest of the second probes 40B, serve as the secondarily adjusted set. It primarily lies in that in the multi-probe matching hole 333C, the primarily adjusted set has larger influence on the impedance of the whole than the secondarily adjusted set. Therefore, there can be only the primarily adjusted set being fine adjusted in impedance matching to attain that the outer diameters of two adjacent barrels 44 are larger than the smallest distance therebetween. For example, in FIG. 10e, the primarily adjusted set is taken between the left second probe 40B and the first probe 40A, so this condition is satisfied. However, the secondarily adjusted set is taken between the right second probe 40B and the first probe 40A, which is unnecessary to satisfy this condition.

It can be known from FIG. 10b to FIG. 10d that in the condition that the middle die 33 includes the multi-probe matching hole 333C, the middle die 33 also includes other middle guiding holes only for the barrel of a single spring probe to be inserted therein, which may be mostly guidance holes, but may also include matching holes (also called single probe matching hole). In FIG. 10b to FIG. 10d, a second probe 40B is located in the multi-probe matching hole 333C, and another second probe 40B is inserted in a single probe matching hole 333D (like the second middle guiding hole in the first preferred embodiment) located adjacent to the multi-probe matching hole 333C. In this arrangement, not only the adjustment of the outer diameters D1, D2 of the barrels of the spring probes 40A, 40B located in the multi-probe matching hole 333C can be performed as described in the preceding paragraph, but the adjustment of the width W3 of the single probe matching hole 333D and/or the outer diameter D2 of the barrel of the spring probe 40B accommodated therein can be also performed in the condition that the difference between the width W3 of the single probe matching hole 333D (as shown in FIG. 10b) and the outer diameter D2 of the barrel of the spring probe 40B accommodated therein is larger than or equal to 10 μm (i.e. W3−D2≥10 μm), so as to adjust the impedance between the spring probe 40B located in the single probe matching hole 333D and the spring probe 40A located in the multi-probe matching hole 333C.

The middle die 33 of the probe head, and a first probe 40A and three second probes 40B, which require impedance matching, are shown in FIG. 11a to FIG. 11d. The first probe 40A is adapted to transmit a test signal. The second probes 40B are adapted to transmit a ground signal. The arrangements of the first and second probes 40A, 40B shown in FIG. 11a to FIG. 11d are completely the same, but the arrangements of the middle guiding hole are different. As shown in FIG. 11a, the pitches P1, P2, P3 of three second probes 40B from the first probe 40A are unequal.

In FIG. 11a, the first and second probes 40A, 40B are disposed in the first and second middle guiding holes 333A, 333B of the middle die 33 in a one-to-one manner, similar to the above-described cases of the first to third preferred embodiments, thereby defined with a first difference (i.e. W1-D1) and three second differences (i.e. W2-D2). In this arrangement, the first and second outer diameters D1, D2 of the first and second probes 40A, 40B and/or the first and second widths W1 W2 of the first and second middle guiding holes 333A, 333B can be adjusted under the condition that at least one of the first and second differences is larger than or equal to 10 μm (that means at least one of the first and second middle guiding holes 333A, 333B is the matching hole, and for example, in FIG. 11a only the first middle guiding hole 333A is the matching hole), such that the impedance between the first and second probes 40A, 40B can be fine adjusted to satisfy the requirement of impedance matching.

In FIG. 11b to FIG. 11d, the barrel 44 of the first probe 40A and the barrel 44 of at least one second probe 40B are located in a multi-probe matching hole 333C. FIG. 11b to FIG. 11d are similar to the above-described case of the fourth preferred embodiment, wherein the adjustment of the outer diameters D1, D2 of the barrels of the spring probes 40A, 40B can be performed under the condition that the outer diameters of two adjacent barrels 44 located in the multi-probe matching hole 333C (that means there can be only a pair of spring probes satisfying this condition) are larger than the smallest distance therebetween (such as shown in FIG. 11b, D1>d, D2>d), such that the impedance between the first and second probes 40A, 40B can be fine adjusted to satisfy the requirement of impedance matching.

No matter the spring probes 40A, 40B are disposed in the middle guiding holes 333A, 333B of the middle die 33 in a one-to-one manner, or there is the situation that a plurality of spring probes 40A, 40B are disposed in the multi-probe matching hole 333C, the spring probes 40A, 40B are disposed in the lower guiding holes 323 of the lower die 32 in a one-to-one manner. Each lower guiding hole 323 may only have a single bore diameter (like the lower guiding hole 16 in FIG. 1). Alternatively, as described above, each lower guiding hole 323 may be stair-shaped, thereby having a relatively wider portion 324 and a relatively narrower portion 325, as shown in FIG. 2. In this way, the relatively wider portion 324 can be only slightly larger than the outer diameter of the barrel 44 to attain the effect of guiding and maintaining the position of the barrel 44, which can further ensure the relative positions between the barrels 44 and the middle guiding holes 333A, 333B where they are located, and the relative position between the barrels 44 of the adjacent spring probes 40A, 40B, making the impedance matching effect relatively more stable.

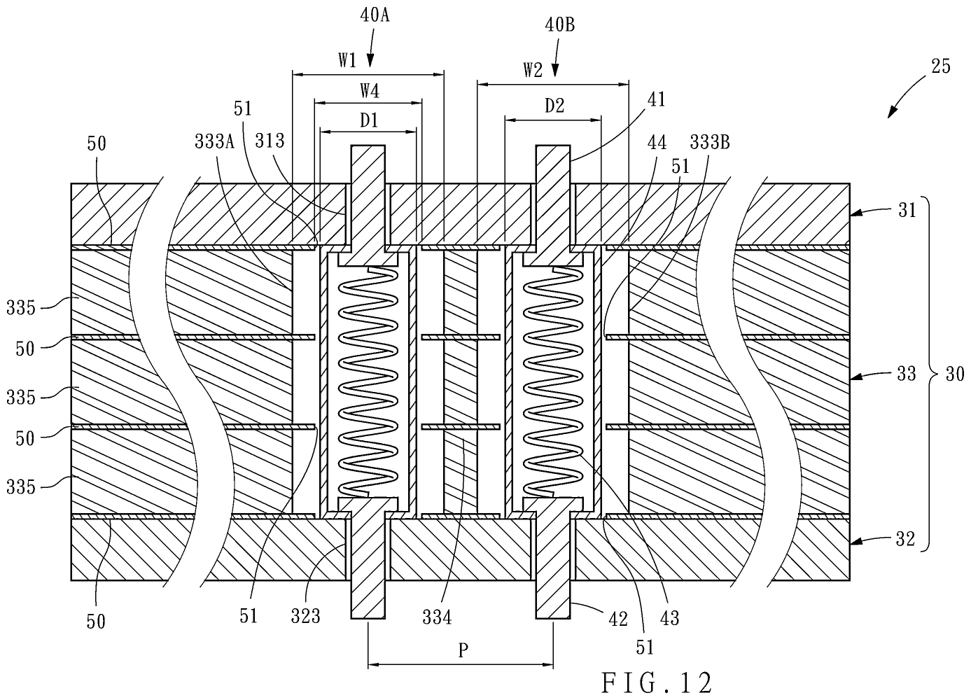

Referring to FIG. 12, a probe head 25 according to a fifth preferred embodiment of the present invention is similar to the above-described probe head 21 of the first preferred embodiment, but the primary difference therebetween lies in that the probe head 25 of this embodiment further includes four insulating positioning films 50, and the middle die 33 in this embodiment is composed of three boards 335. The insulating positioning films 50 are respectively disposed between the boards 335 of the middle die 33 and between the middle die 33 and the upper and lower dies 31, 32. Each insulating positioning film 50 includes a plurality of positioning holes 51. The barrels 44 of the spring probes 40A, 40B are inserted in the positioning holes 51 of each insulating positioning film 50 respectively, and the difference between the width W4 of each positioning hole 51 and the outer diameter D1 D2 of the barrel 44 accommodated therein is smaller than 10 micrometers. In other words, the width W4 of the positioning hole 51 is smaller than the width of the above-described matching hole (the middle guiding holes 333A, 333B in this embodiment are matching holes).

As a result, in the assembling process of the probe head 25, the positioning holes 51 of the insulating positioning films 50 can bring the effect of positioning the spring probes 40A, 40B to facilitate the probe installation process. Such insulating positioning film 50 is also applicable to other embodiments of the present invention. The middle die 33 is unlimited to be composed of a single board or a plurality of boards, and the amount of the insulating positioning film 50 is unlimited, as long as there is an insulating positioning film 50 clamped between the upper die 31 and the middle die 33, or between the middle die 33 and the lower die 32, or between the boards 335 of the middle die 33. That means, as long as it is located between the upper and lower dies 31, 32, it is adapted for the barrels 44 of the spring probes 40A, 40B to be inserted in the positioning holes 51 of the insulating positioning film 50 to attain the effect of convenience of probe installation.

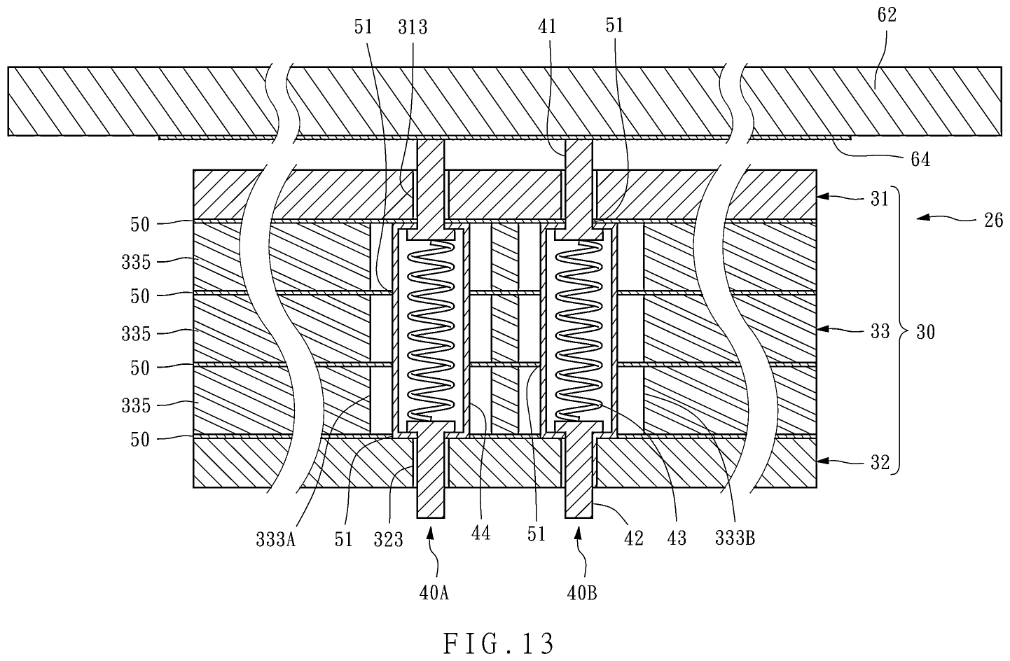

Referring to FIG. 13, a probe head 26 according to a sixth preferred embodiment of the present invention is similar to the probe head 25 of the above-described fifth preferred embodiment, but the primary difference therebetween lies in that the positioning holes 51 of the insulating positioning films 50 in this embodiment are even smaller, so that the bore walls will be abutted against the barrels 44 of the spring probes 40A, 40B. The positioning holes 51 of the highest insulating positioning film 50 are even adapted for the upper abutting sections 41 of the spring probes 40A, 40B to be inserted therethrough, and the bore walls of the positioning holes 51 are abutted against the upper abutting sections 41 of the spring probes 40A, 40B. Besides, the insulating positioning film 50 may be provided thereon with circuits (not shown), and a part of the spring probes are electrically connected with the circuits of the insulating positioning film 50 by the barrels 44 or upper abutting sections 41 thereof being abutted against the positioning holes 51, so as to transmit test signal or power, such as signal fan out or power fan out.

In other words, the insulating positioning film 50 not only may have the effect of positioning the spring probes, but also may be arranged with circuits for transmitting test signal or power together with the spring probes. Such insulating positioning film 50 is also applicable to other embodiments of the present invention. The middle die 33 is unlimited to be composed of a single board or a plurality of boards, and the amount of the insulating positioning film 50 is unlimited, as long as there is an insulating positioning film 50 clamped between the upper die 31 and the middle die 33, or between the middle die 33 and the lower die 32, or between the boards 335 of the middle die 33. That means, as long as it is located between the upper and lower dies 31, 32, both the effects of positioning the spring probes and transmitting test signal or power can be attained at the same time by the positioning holes 51 of the insulating positioning film 50.

It deserves to be mentioned that as shown in FIG. 13, the bottom surface of the circuit board 62 (i.e. the above-described space transformer or main circuit board) disposed above the probe head 26 may be provided with a circuit film 64. The circuit film 64 is similar to the insulating positioning film 50 in this embodiment, which is an insulating film arranged with circuits, but the circuit film 64 has no positioning hole. The circuit film 64 may be provided with through holes (not shown) for the upper abutting sections 41 of a part of the spring probes to be inserted through the through holes of the circuit film 64 to be abutted against electrically conductive contacts (not shown) on the bottom surface of the circuit board 62. The upper abutting sections 41 of a part of the spring probes (such as the spring probes 40A, 40B shown in FIG. 13) can be abutted against the circuits of the circuit film 64 to be electrically connected with each other.

Furthermore, the above-described insulating positioning film 50 may (but unlimited to) be made of wave absorbing material. For example, the composition of the wave absorbing material includes ferrite, barium titanate, metal micro powder, graphite, silicon carbide, and so on, capable of absorbing electromagnetic waves to prevent the signals of the spring probes from interference with each other.

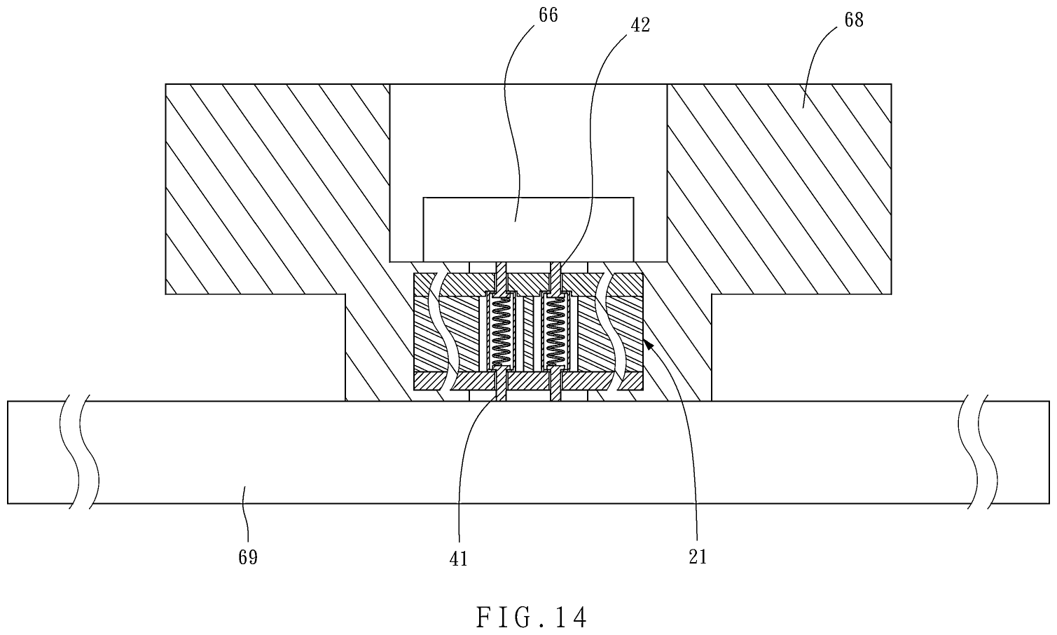

At last, it should be mentioned that the probe head provided by the present invention is not only able to be combined with the aforementioned space transformer and/or main circuit board to compose the probe card so as to be applied to chip probing (also called CP for short), but the probe head provided by the present invention is also applicable to after-encapsulation IC final tests (also called FT for short). As shown in FIG. 14, the probe head 21 and the integrated circuit 66 (also called IC for short) under test are disposed in a socket 68. The socket 68 is fixed to a circuit board 69. The upper abutting section 41 and the lower abutting section 42 of the spring probe of the probe head 21 are abutted against the electrically conductive contact of the circuit board 69 and the electrically conductive contact of the integrated circuit 66 respectively, such that the integrated circuit 66 can be tested through the circuit board 69 and the probe head 21.

At last, it should be mentioned again that the constituent elements disclosed in the above embodiments of the present invention are only taken as examples for illustration, not intended to limit the scope of the present invention. The substitution or variation of other equivalent elements should be included within the scope of the following claims of the present invention.

What is claimed is:

1. A probe head having spring probes, which comprises:
an upper die comprising a plurality of upper guiding holes;
a lower die comprising a plurality of lower guiding holes;
a middle die disposed between the upper die and the lower die, the middle die comprising a plurality of middle guiding holes; and
a plurality of spring probes each comprising an upper abutting section, a lower abutting section, a spring section connecting the upper abutting section and the lower abutting section, and a barrel disposed on a periphery of the spring section, the upper abutting sections of the spring probes being inserted in the upper guiding holes respectively, the lower abutting sections of the spring probes being inserted in the lower guiding holes respectively, the barrels of the spring probes being inserted in the middle guiding holes respectively;
wherein the spring probes comprise a first probe and a second probe, which are located adjacent to each other; the barrel of the first probe and the barrel of the second probe have a first outer diameter and a second outer diameter respectively; the middle guiding holes comprise a first middle guiding hole and a second middle guiding hole, which accommodate the first probe and the second probe respectively; the first middle guiding hole and the second middle guiding hole have a first width and a second width respectively; a difference between the first width and the first outer diameter is defined as a first difference; a difference between the second width and the second outer diameter is defined as a second difference; a difference between the first outer diameter and the second outer diameter is defined as a third difference; the probe head satisfies at least one of following three conditions: the first difference being larger than or equal to 10 micrometers, the second difference being larger than or equal to 10 micrometers, and the third difference being larger than or equal to 5 micrometers.

2. The probe head having spring probes as claimed in claim 1, wherein the first probe is adapted to transmit a test signal; the second probe is adapted to transmit a ground signal; the probe head comprises a plurality of said second probes and a plurality of said second middle guiding holes accommodating the second probes respectively, thereby defined with a plurality of said second differences; each of the second probes has a pitch from the first probe; the pitches of the second probes from the first probe are unequal to each other; at least one of the first difference and the second differences is larger than or equal to 10 micrometers.

3. The probe head having spring probes as claimed in claim 1, wherein the first probe is adapted to transmit a first test signal; the second probe is adapted to transmit a second test signal; the probe head comprises a plurality of said second probes and a plurality of said second middle guiding holes accommodating the second probes respectively, thereby defined with a plurality of said second differences; each of the second probes has a pitch from the first probe; the pitches of the second probes from the first probe are unequal to each other; at least one of the first difference and the second differences is larger than or equal to 10 micrometers.

4. The probe head having spring probes as claimed in claim 1, wherein the probe head satisfies at least one of following three conditions: the first difference being larger than or equal to 12 micrometers, the second difference being larger than or equal to 12 micrometers, and the third difference being larger than or equal to 7 micrometers.

5. The probe head having spring probes as claimed in claim 4, wherein the probe head satisfies at least one of following three conditions: the first difference being larger than or equal to 14 micrometers, the second difference being larger than or equal to 14 micrometers, and the third difference being larger than or equal to 10 micrometers.

6. The probe head having spring probes as claimed in claim 1, wherein each of the lower guiding holes is stair-shaped, thereby having a relatively wider portion and a relatively narrower portion; the barrel of each of the spring probes is partially located in the relatively wider portion; the lower abutting section of each of the spring probes is inserted in the relatively narrower portion.

7. The probe head having spring probes as claimed in claim 1, wherein the probe head further comprises an insulating positioning film; the insulating positioning film is located between the upper die and the lower die; the insulating positioning film comprises a plurality of positioning holes; the barrels of the spring probes are inserted in the positioning holes respectively; a difference between a width of each of the positioning holes and an outer diameter of the barrel accommodated therein is smaller than 10 micrometers.

8. The probe head having spring probes as claimed in claim 7, wherein the insulating positioning film is provided thereon with a circuit electrically connected with the spring probe.

9. The probe head having spring probes as claimed in claim 7, wherein the insulating positioning film is made of wave absorbing material.

10. A probe head having spring probes, which comprises:
an upper die comprising a plurality of upper guiding holes;
a lower die comprising a plurality of lower guiding holes;
a middle die disposed between the upper die and the lower die, the middle die comprising a plurality of middle guiding holes; and
a plurality of spring probes each comprising an upper abutting section, a lower abutting section, a spring section connecting the upper abutting section and the lower abutting section, and a barrel disposed on a periphery of the spring section, the upper abutting sections of the spring probes being inserted in the upper guiding holes respectively, the lower abutting sections of the spring probes being inserted in the lower guiding holes respectively, the barrels of the spring probes being disposed in the middle guiding holes of the middle die, the barrel of each of the spring probes having an outer diameter;
wherein the middle guiding holes comprise a multi-probe matching hole; the barrels of a plurality of said spring probes are located in the multi-probe matching hole; the outer diameters of two adjacent said barrels located in the multi-probe matching hole are larger than a smallest distance between said two adjacent said barrels.

11. The probe head having spring probes as claimed in claim 10, wherein the spring probes comprise a first probe for transmitting a test signal, and a plurality of second probes located adjacent to the first probe for transmitting a ground signal; each of the second probes has a pitch from the first probe; the pitches of the second probes from the first probe are unequal to each other; the barrel of the first probe and the barrel of at least one said second probe are located in the multi-probe matching hole.

12. The probe head having spring probes as claimed in claim 10, wherein the spring probes comprise a first probe for transmitting a first test signal, and a plurality of second probes located adjacent to the first probe for transmitting a second test signal; each of the second probes has a pitch from the first probe; the pitches of the second probes from the first probe are unequal to each other; the barrel of the first probe and the barrel of at least one said second probe are located in the multi-probe matching hole.

13. The probe head having spring probes as claimed in claim 10, wherein the middle guiding holes further comprise a single probe matching hole located adjacent to the multi-probe matching hole; the barrel of one of said spring probes is inserted in the single probe matching hole; a difference between a width of the single probe matching hole and an outer diameter of the barrel accommodated therein is larger than or equal to micrometers.

14. The probe head having spring probes as claimed in claim 10, wherein each of the lower guiding holes is stair-shaped, thereby having a relatively wider portion and a relatively narrower portion; the barrel of each of the spring probes is partially located in the relatively wider portion; the lower abutting section of each of the spring probes is inserted in the relatively narrower portion.

15. The probe head having spring probes as claimed in claim 10, wherein the probe head further comprises an insulating positioning film; the insulating positioning film is located between the upper die and the lower die; the insulating positioning film comprises a plurality of positioning holes; the barrels of the spring probes are inserted in the positioning holes respectively; a difference between a width of each of the positioning holes and an outer diameter of the barrel accommodated therein is smaller than 10 micrometers.

16. The probe head having spring probes as claimed in claim 15, wherein the insulating positioning film is provided thereon with a circuit electrically connected with the spring probe.

17. The probe head having spring probes as claimed in claim 15, wherein the insulating positioning film is made of wave absorbing material.
